(19) United States
(12) Patent Application Publication
(10) Pub. No.: US 2009/0204252 A1
(43) Pub. Date: Aug. 13, 2009

(54) SUBSTRATE PROCESSING METHOD AND APPARATUS, METHOD FOR MANUFACTURING SEMICONDUCTOR DEVICE AND STORAGE MEDIUM

(75) Inventors: Hidenori MIYOSHI, Nirasaki-shi (JP); Kenji Ishikawa, Kawasaki-shi (JP); Hideki Tateishi, Tokyo (JP); Masakazu Hayashi, Kawasaki-shi (JP); Nobuyuki Nishikawa, Kawasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 12/391,852

(22) Filed: Feb. 24, 2009

Related U.S. Application Data
(63) Continuation of application No. PCT/JP2007/065759, filed on Aug. 10, 2007.

(30) Foreign Application Priority Data
Aug. 24, 2006 (JP) 2006-228126
Jun. 5, 2007 (JP) 2007-149614

(51) Int. Cl. C23G 1/02; H01L 21/34; C09K 3/00; B01J 19/00; C23G 1/00; B08B 5/00; G06F 17/00

(52) U.S. Cl. 700/121; 438/795; 252/182.12; 422/129; 134/2; 134/3; 134/56 R; 257/E21.46

(57) ABSTRACT

A substrate processing method includes a first step of forming a metal complex by allowing a processing gas containing an organic compound to be adsorbed by a metal layer formed on a target substrate while setting the target substrate to be kept at a first temperature, and a second step of sublimating the metal complex by heating the target substrate to maintain it at a second temperature higher than the first temperature.

This application is a Continuation Application of PCT International Application No. PCT/JP2007/065759 filed on Aug. 10, 2007, which designated the United States.

### FIELD OF THE INVENTION

The present invention relates to a substrate processing technology in general; and, more particularly, to a substrate processing method for performing substrate processing by using an organic compound; a semiconductor device manufacturing method using the substrate processing method; a substrate processing apparatus for performing the substrate processing by using the organic compound; and a storage medium storing therein a program to be used in operating the substrate processing apparatus.

### BACKGROUND OF THE INVENTION

Along with performance improvement achieved in semiconductor devices, Cu having a low resistance has been widely employed as a wiring material for a high-performance semiconductor device. Since, however, Cu is likely to be easily oxidized, a Cu wiring exposed through an interlayer insulating film may be oxidized during a process of forming a multi-layered wiring structure of Cu by using, for example, a damascene method. For this reason, such a gas as HN₃ or H₂ having reducibility has been used to remove the oxidized CU by reduction.

However, in case that NH₃ or N₂ is used, since the processing temperature for the reducing process of Cu needs to be set high, a damage can be inflicted on an interlayer insulating film formed of a so-called Low k material around the Cu wiring. For this reason, there has been proposed a method for performing the reduction of Cu at a low temperature of about 200° C. by using a carboxylic acid such as formic acid, acetic acid, or the like as a processing gas by gasifying it.

However, in the reducing process using the organic compound such as the formic acid or the acetic acid, a part of Cu may be etched by being sublimated as a metal-organic compound complex. Further, the sublimated metal-organic compound complex may be thermally decomposed in a processing space in which a target substrate is processed, resulting in adherence of Cu to the inside of a processing vessel such as the surface of an inner wall for defining the processing space, a supporting table for sustaining the target substrate thereon, or the like.

Further, the adhered Cu may be etched again by the formic acid or acetic acid and can be reattached to the target substrate. In the event that Cu is reattached to the target substrate, there is a concern that the characteristic of the semiconductor device may be deteriorated.

(Patent Document 1) Japanese Patent No. 3373499

(Patent Document 2) Japanese Patent Laid-open Publication No. 2006-216673

(Non-Patent Document 1) David R. Lide (ed), CRC Handbook of Chemistry and Physics, 84^{th} Edition

(Non-Patent Document 2) E. Mack et al., J. Am. Chem. Soc., 617, (1923)

### SUMMARY OF THE INVENTION

In view of the foregoing, the present invention provides an inventive and useful substrate processing method, a semiconductor device manufacturing method, a substrate processing apparatus and a storage medium, capable of solving the aforementioned problems.

To be more specific, the present invention provides a substrate processing method capable of performing substrate processing in a cleanly manner by using an organic compound gas; a semiconductor device manufacturing method using the substrate processing method; a substrate processing apparatus capable of performing the substrate processing in a cleanly manner by using the organic compound gas; and a storage medium storing therein a program to be used in operating the substrate processing apparatus.

In accordance with a first aspect of the present invention, there is provided a substrate processing method including: a first step of forming a metal complex by allowing a processing gas containing an organic compound to be adsorbed by a metal layer formed on a target substrate while setting the target substrate to be kept at a first temperature; and a second step of sublimating the metal complex by heating the target substrate to maintain it at a second temperature higher than the first temperature.

Here, it may be also possible to perform a chamber cleaning method for sublimating a residual metal complex inside a processing vessel (chamber), which is used for carrying out the substrate processing method by using the processing gas containing the organic compound, by heating the chamber up to the second temperature.

By using the substrate processing method, it becomes possible to perform the substrate treatment by the organic compound gas in a cleanly manner. Further, by performing the above-stated chamber cleaning process, the substrate treatment can be performed in a clean environment.

In accordance with a second aspect of the present invention, there is provided a manufacturing method for a semiconductor device including a metal wiring and an insulating layer, including: a first step of forming a metal complex by allowing a processing gas containing an organic compound to be adsorbed by a metal layer formed on a target substrate while setting the target substrate to be kept at a first temperature; and a second step of sublimating the metal complex by heating the target substrate to be maintained at a second temperature higher than the first temperature.

By employing the semiconductor device manufacturing method, it becomes possible to perform the manufacture of the semiconductor device in a cleanly manner by using the substrate treatment with the organic compound gas.

In accordance with a third aspect of the present invention, there is provided a substrate processing apparatus including: a processing vessel having therein a processing space in which a target substrate having a metal layer formed thereon is processed; a gas control unit for controlling a supply of a processing gas into the processing space; and a temperature control unit for controlling temperature of the target substrate, wherein the temperature control unit controls the temperature of the target substrate in sequence to be kept at a first temperature for forming a metal complex by allowing a processing gas containing an organic compound to be adsorbed by the metal layer and then to be maintained at a second temperature for sublimating the metal complex.

By using the substrate processing apparatus, it becomes possible to perform the substrate treatment by the organic compound gas in a cleanly manner.

In accordance with a fourth aspect of the present invention, there is provided a storage medium for storing therein a computer-executable program which controls, when executed, a substrate processing method to be carried out by a substrate processing apparatus including: a processing vessel having therein a processing space in which a target substrate having a metal layer formed thereon is processed; a gas control unit for controlling a supply of a processing gas into the processing space; and a temperature control unit for controlling temperature of the target substrate.

The substrate processing method includes: a first step of forming a metal complex by allowing a processing gas containing an organic compound to be adsorbed by a metal layer formed on a target substrate while setting the target substrate to be kept at a first temperature; and a second step of sublimating the metal complex by heating the target substrate to be maintained at a second temperature higher than the first temperature.

By using the storage medium, it becomes possible to perform the substrate treatment by the organic compound gas in a cleanly manner.

In accordance with a fifth aspect of the present invention, there is provided a method for removing a metal deposit adhered inside a processing vessel having therein a processing space in which a target substrate having a metal layer formed thereon is processed, including: a step of controlling an internal temperature of the processing vessel and a pressure inside the processing space so as to sublimate the metal deposit.

By using the metal deposit removing method, it becomes possible to perform the substrate treatment by the organic compound gas in a cleanly manner.

In accordance with a sixth aspect of the present invention, there is provided a substrate processing apparatus including: a processing vessel having therein a processing space in which a target substrate having a metal layer formed thereon is processed; a supporting table for sustaining the target substrate thereon; a gas control unit for controlling a supply of a processing gas containing an organic compound into the processing space; a pressure control unit for controlling a pressure inside the processing vessel; and a temperature control unit for controlling temperature of at least one of an inner wall surface of the processing vessel and the supporting table to which a metal is adhered.

The gas control unit controls the supply of the processing gas into the processing vessel to be stopped in a state wherein the target substrate is not accommodated in the processing vessel, and the pressure control unit and the temperature control unit control the pressure and the temperature, respectively, such that the metal deposit adhered on the inner wall surface of the processing vessel and the supporting table is sublimated.

By using the substrate processing apparatus, it becomes possible to perform the substrate treatment by the organic compound gas in a cleanly manner.

In accordance with a seventh aspect of the present invention, there is provided a storage medium for storing therein a computer-executable program which controls, when executed, a metal deposit removing method to be carried out by a substrate processing apparatus including: a processing vessel having therein a processing space in which a target substrate having a metal layer formed thereon is processed; a supporting table for sustaining the target substrate thereon; a gas control unit for controlling a supply of a processing gas containing an organic compound into the processing space; a pressure control unit for controlling a pressure inside the processing vessel; and a temperature control unit for controlling a temperature of at least one of an inner wall surface of the processing vessel and the supporting table to which a metal is adhered.

In the metal deposit removing process, an internal temperature of the processing vessel and a pressure inside the processing space are controlled so as to sublimate the metal deposit.

By using the storage medium, it becomes possible to perform the substrate treatment by the organic compound gas in a cleanly manner.

In accordance with the present invention described above, there is provided a substrate processing method capable of performing a clean substrate treatment by an organic compound gas; a semiconductor device manufacturing method using the substrate processing method; a substrate processing apparatus capable of performing a clean substrate treatment by an organic compound gas; and a storage medium storing therein a program to be used in operating the substrate processing apparatus.

### BRIEF DESCRIPTION OF THE DRAWINGS

FIG. 1 presents a flowchart to describe a substrate processing method in accordance with an embodiment of the present invention.

FIG. 2 sets forth a diagram illustrating a substrate processing apparatus for use in the substrate processing method of FIG. 1 in accordance with the embodiment of the present invention.

FIG. 3 depicts a diagram showing a substrate processing apparatus for use in the substrate processing of FIG. 1 in accordance with another embodiment of the present invention.

FIG. 4 provides a diagram illustrating a substrate processing apparatus for use in the substrate processing of FIG. 1 in accordance with still another embodiment of the present invention.

FIG. 5 provides a comparison of vapor pressure of solid Cu with that of CuO.

FIG. 6 describes an equilibrium oxygen concentration of CuO.

FIG. 7 is a diagram illustrating a substrate processing apparatus for use in the substrate processing of FIG. 1 in accordance with still another embodiment of the present invention.

FIG. 8 depicts a diagram illustrating a substrate processing apparatus for use in the substrate processing of FIG. 1 in accordance with still another embodiment of the present invention.

FIG. 9 sets forth a diagram showing the entire configuration of a substrate processing system for use in the substrate processing of FIG. 1.

FIG. 10 is a chart showing an analysis result of a gas separated from a target substrate.

FIG. 11 is a chart showing an analysis result performed on the thickness of a copper oxide formed on a metal layer and a detection amount of Cu vaporized by processing.

FIG. 12 sets forth an analysis result of the thickness of a removed film.

FIG. 13 presents a modification example of the substrate processing apparatus.

FIG. 14 illustrates another modification example of the substrate processing apparatus.

FIG. 15A is a first diagram illustrating a semiconductor device manufacturing apparatus in accordance with a third embodiment of the present invention.

FIG. 15B is a second diagram illustrating the semiconductor device manufacturing apparatus in accordance with the third embodiment of the present invention.

FIG. 15C is a third diagram illustrating the semiconductor device manufacturing apparatus in accordance with the third embodiment of the present invention.

FIG. 15D is a fourth diagram illustrating the semiconductor device manufacturing apparatus in accordance with the third embodiment of the present invention.

FIG. 15E is a fifth diagram illustrating the semiconductor device manufacturing apparatus in accordance with the third embodiment of the present invention.

### DETAILED DESCRIPTION OF THE EMBODIMENTS

Hereinafter, embodiments of the present invention will be described.

### First Embodiment

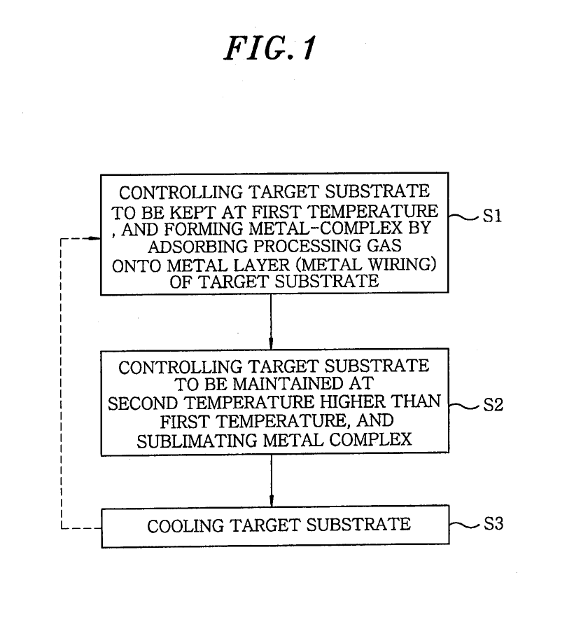

FIG. 1 is a flowchart for describing a substrate processing method in accordance with a first embodiment of the present invention.

Referring to FIG. 1, in a step 1 (in the drawing, it is defined as a step S1, and the other following steps will be numbered likewise), a target substrate, which has a metal layer (e.g., a metal wiring or the like) whose surface is oxidized and thus provided with a metal oxide film, is disposed in a processing space inside a processing vessel, and the target substrate is controlled (set) to be kept at a first temperature. Here, an organic compound gas such as formic acid or the like is introduced into the processing vessel (processing space) to be adsorbed in the surface of the metal layer on the target substrate, thereby obtaining a metal-complex (metal-organic compound complex).

To suppress sublimation of the metal-organic compound complex formed in the step 1, it is preferable to set the temperature of the target substrate to be at a low level. For example, the first temperature is preferably of a level at which the vapor pressure of the metal-organic compound complex becomes lower than the pressure inside the processing space.

For example, when using the vapor of the formic acid as a processing gas, it is preferable to set the first temperature to be not higher than the room temperature. As stated, by controlling the first temperature in the step 1, sublimation of the metal-organic compound complex is suppressed and metal is prevented from adhering to the inner side of the processing vessel. Prior to proceeding to a step 2 (in which the temperature of the target substrate is raised) after performing the step 1 for a preset time period, the supply of the processing gas into the processing space is stopped.

Then, in the step 2, while the supply of the processing gas into the processing space remains to be ceased, the target substrate having the metal-organic compound complex formed on the surface of the metal layer is heated under a non-reactive gas atmosphere or a depressurized atmosphere up to a second temperature, which is higher than the first temperature in the step 1. Accordingly, the metal-organic compound complex is sublimated and removed. Through the steps 1 and 2, the metal oxide film formed on the metal layer can be removed.

In the step 2, since the processing gas (organic compound gas such as the vapor of formic acid or the like) is not supplied into the processing space, etching of a metal adhered to the inside of the processing vessel due to decomposition of a part of the sublimated metal-organic is suppressed, so that reattachment of the etched metal to the target substrate is suppressed. Further, as for the metal adhered to the inside of the processing vessel, it may be also possible to remove it by increasing the temperature inside the processing vessel and lowering the pressure inside the processing space. When performing the removal of the metal deposit, it is preferable to set the vapor pressure of the metal deposit at the internal temperature of the processing vessel to be higher than the pressure inside the processing space. In general, since the vapor pressure of the metal deposit is low, it is preferable to set the pressure in the processing space to be as low as possible.

Further, if the heated target substrate is exposed to the atmosphere while remaining at its high temperature (e.g., about 100° C. or above), there is a likelihood that the metal may be re-oxidized due to oxygen in the atmosphere. Therefore, it may be preferable to perform cooling of the target substrate, if necessary, by preparing a third step 3.

The above-described substrate processing method is characterized in that the step 1 for forming the metal-organic compound complex on the surface of the metal layer is conducted substantially separately from the step 2 for sublimating the metal-organic compound complex thus formed. That is, in the step 1 in which the processing gas is supplied, the target substrate is set to a low temperature (first temperature) to suppress the sublimation of the metal-organic compound complex being formed. Meanwhile, in the step 2 in which the supply of the processing gas is stopped, the temperature of the target substrate is set to a high temperature (second temperature) to facilitate the sublimation of the formed metal-organic compound complex actively while suppressing occurrence of another etching of metal.

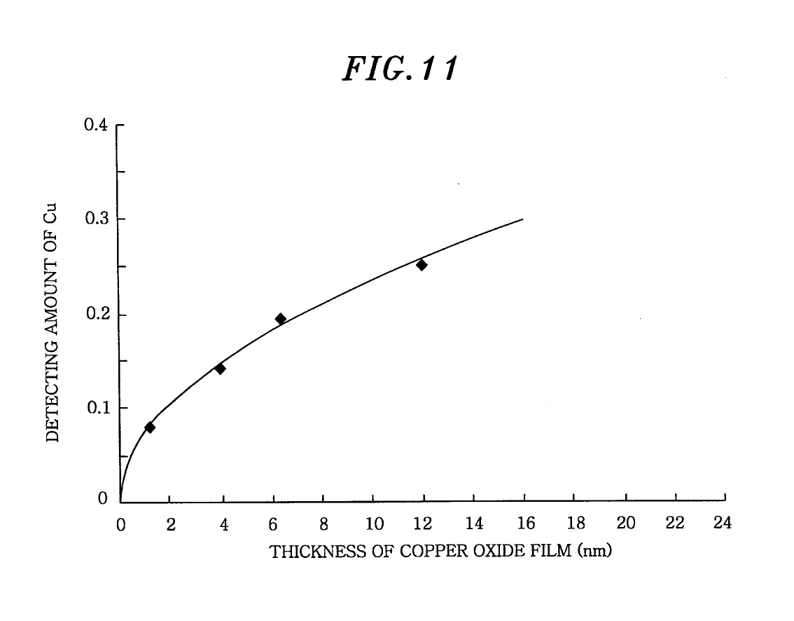

Accordingly, in the substrate processing method in accordance with the present embodiment, it is possible to prevent contamination of the target substrate (devices, wiring, insulating layers and so forth formed on the target substrate) due to the reattachment of the metal etched by the organic compound gas and to perform the substrate processing in a clean environment. For example, by using the above-described substrate processing method, it is possible to manufacture a semiconductor device having a multi-layered Cu wiring structure by removing a Cu oxide film formed on a Cu wiring (specific example of this will be elaborated later in a fourth embodiment with reference to FIG. 11A to 15E).

Further, even in case that the metal oxide film to be removed is thick, its removal can be still carried out efficiently by repeatedly performing the steps 1 to 3 (or steps 1 and 2).

Moreover, even in case of a conventional substrate processing method, by employing the above-stated metal deposit removing method while the target substrate is not in the processing vessel (the method of increasing the internal temperature of the processing vessel to which the metal is adhered while lowering the pressure inside the processing space, e.g., the method of setting the vapor pressure of the metal deposit under the internal temperature of the processing vessel to be higher than the pressure inside the processing space), it is possible to remove the metal deposit inside the processing vessel while suppressing reattachment of the metal to the target substrate.

Further, in the processes of steps 1 and 2 or from 1 to 3, it is preferable to maintain the target substrate under the depressurized atmosphere or non-reactive atmosphere and carry out the processes continually and rapidly.

In this regard, the above-described substrate processing method can be applied in using a so-called cluster (multi-chamber) substrate processing apparatus having a plurality of processing vessels (processing spaces) The cluster substrate processing apparatus has a configuration in which the processing vessels are connected to a transfer chamber which is maintained in a depressurized state or filled with a non-reactive gas. In such case, the processes of the steps 1 and 2 or the steps 1 to 3 are performed in separate processing vessels (processing spaces) For example, the step 1 may be performed in a first processing vessel (processing space), and afterward, the step 2 and the step 3 are carried out in a second processing vessel (processing space) and in a third processing vessel (processing space) respectively, after the target substrate is transferred there in sequence.

As described above, as a result of performing the steps presented in the above-described substrate processing method in the cluster substrate processing apparatus, oxidation of the metal layer due to the exposure of the target substrate to oxygen, adherence of contaminants to the target substrate, and the like can be suppressed, and the substrate processing can be carried out in a clean environment. Further, since the first processing vessel (processing space) into which the processing gas is supplied and in which the formation of the metal-organic compound complex is carried out is separated from the second processing vessel into which no processing gas is supplied and in which the sublimation of the metal compound complex is carried out, reattachment of the metal can be prevented more efficiently.

Further, in the above-stated substrate processing method, it may be also possible to perform the processes of the steps 1 and 2 or steps 1 to 3 in a single processing vessel (processing space). In such case, the structure of the substrate processing apparatus can be simplified, thus achieving reduction of costs for the substrate processing (manufacture of the semiconductor device). Moreover, even in case of performing the processes of the steps 1 and 2 or steps 1 to 3 in the same processing vessel, the substrate processing can be realized in a cleaner environment in which the reattachment of the metal is suppressed, in comparison with the conventional substrate processing method (i.e., the method of performing the formation and the sublimation of the metal-organic compound complex together.

Now, a configuration example of the substrate processing apparatus for employing the substrate processing method described above will be explained for the case using a cluster substrate processing apparatus.

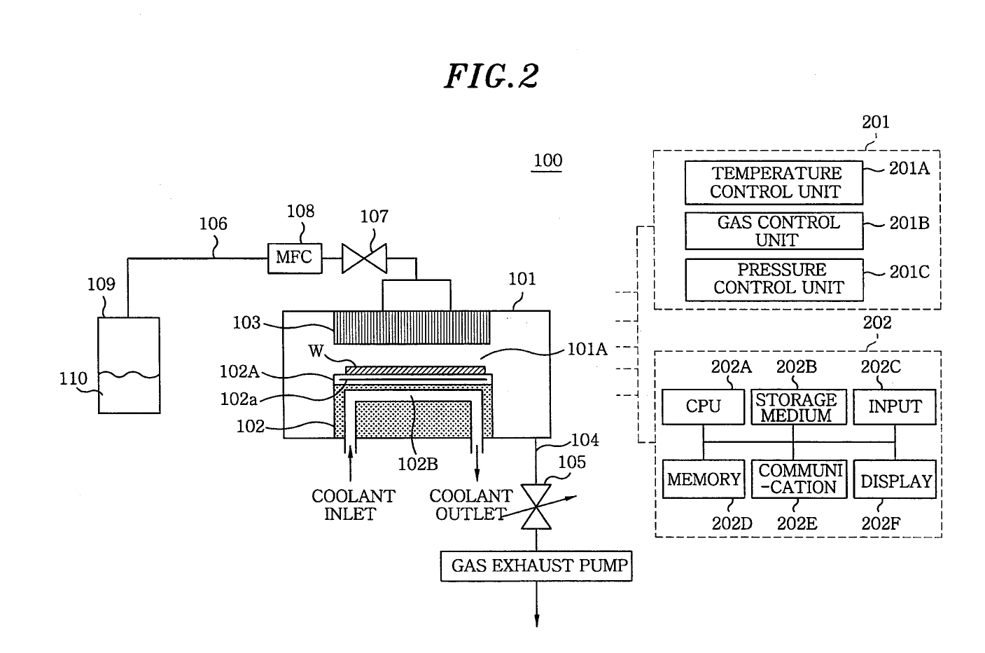

FIG. 2 illustrates a part of the cluster substrate processing apparatus which employs the substrate processing method described in FIG. 1. Specifically, FIG. 2 illustrates a schematic configuration view of a first processing unit 100 for performing the step 1 of FIG. 1.

Referring to FIG. 2, the first processing unit 100 includes therein a processing vessel 101 which defines a first processing space 101A, and a supporting table 102 for supporting a target substrate W thereon is installed in the processing space 101A.

An electrostatic attraction structure 102A for electrostatically attracting and holding the target substrate W is provided on the surface of the supporting table 102. The electrostatic attraction structure 102A includes, for example, an electrode 102a embedded in a dielectric layer made of a ceramic material or the like, and functions to electrostatically attract and hold the target substrate W as a voltage is applied to the electrode.

Further, provided inside the supporting table 102 is a cooling unit 102B formed of a flow path through which a cooling medium made of, e.g., fluorocarbon-based fluid is circulated. In the above structure, temperature control of the supporting table 102 and the electrostatic attraction structure 102A is carried out by a heat exchange by the cooling medium (described as a coolant in the figure), so that the target substrate W supported thereon can be controlled (cooled) to be kept at a desired temperature.

For example, a widely known circulation unit (not shown) is connected with the cooling unit (flow path), and by controlling the temperature or a flow rate of the circulated cooling medium, the temperature control of the target substrate W can be realized. The circulation unit can be referred to as a chiller, for example.

Further, the first processing space 101A is evacuated to vacuum via a gas exhaust line 104 connected to the processing vessel 101 and is maintained in a depressurized state. The gas exhaust line 104 is connected to a gas exhaust pump via a pressure control valve 105, so that the first processing space 101A can be set under the depressurized state of a desired pressure level. In addition, it may be also possible to dispose a vessel for recollecting exhausted organic compound at the rear end of the gas exhaust pump and to recycle the recollected organic compound.

Moreover, a shower head 103 for diffusing a processing gas supplied through a processing gas supply line 106 into the first processing space 101A is provided on one side of the first processing space 101A facing the supporting table 102, and is configured to diffuse the processing gas onto the target substrate W uniformly.

Further, the processing gas supply line 106 for supplying the processing gas into the shower head 103 is connected with a source container 109 which accommodates a liquid or solid source material 110 inside. Further, a valve 107 and a flow rate controller (e.g., a mass flow controller called a MFC in short) 108 for controlling the flow rate of the processing gas are installed on the processing gas supply line 106, whereby start and stop of the supply of the processing gas and the flow rate of the supplied processing gas can be controlled.

For example, the source material 110 is an organic compound such as formic acid or the like and it is vaporized or sublimated in the source container 109. For instance, the formic acid is liquid at room temperature, and a certain amount of it is vaporized at the room temperature. It may be possible to stabilize the vaporization by heating the source container 109.

Further, it may be also possible to set up a configuration in which the source container 109, the processing gas supply line 106, the valve 107, the flow rate controller 108 and so forth are cooled by using the same coolant as supplied to the supporting table 102.

The processing gas provided through the processing gas supply line 106 is supplied into the first processing space 101A through a plurality of gas holes provided in the shower head 103. The processing gas in the first processing space 101A then reaches the target substrate W controlled (cooled) to be maintained at the preset temperature (first temperature) and is adsorbed onto the surface of a metal layer (e.g., a Cu wiring or the like), so that a metal-organic compound complex is formed. Here, when the controlled first temperature is approximately same as the room temperature, there is no need to practically control it, and an active temperature control by, for example, cooling by the cooling medium becomes unnecessary.

Moreover, the temperature of the target substrate W can be adjusted by controlling the attracting force of the electrostatic attraction structure 102A. For example, by increasing the voltage applied to the electrode 102a, the attracting force for the target substrate (i.e., the attracted area thereof) can be enhanced, whereby cooling efficiency can be improved, thereby more efficiently lowering the temperature of the target substrate.

Further, in the process of step 1, the processing performance for the target substrate can be improved by introducing an additional gas to the processing gas. For instance, O₂ or N₂O can be added as an oxidative gas, or H₂ or NH₃ can be added as another reductive gas.

Further, the process of step 1 in the first processing unit 100 is executed by a computer 202 via a controller 201. The computer 202 executes the processes described above based on programs stored in a storage medium 202B. Here, illustration of wiring for the controller 201 and the computer 202 is omitted.

The controller 201 includes a temperature control unit 201A, a gas control unit 201B and a pressure control unit 201C. The temperature control unit 201A controls the temperature of the target substrate W by way of controlling the flow rate and the temperature of the cooling medium flowing through the cooling unit (flow path) 102B. Further, the temperature control unit 201A also controls the temperature of the target substrate W by the control of the voltage applied to the electrode 102a (i.e., by the control of the attracting force).

The gas control unit 201B executes the control of the valve 107 and the flow rate controller 108, and controls start and stop of the supply of the processing gas and the flow rate of the supplied processing gas. The pressure control unit 201C controls the degree of openness of the pressure control valve 105 to control the pressure inside the processing space 101A.

Further, the computer which controls the controller 201 includes a CPU 202A, the storage medium 202B, a memory 202D, a communicating unit 202E and a display unit 202F. For example, the program of the substrate processing method regarding the substrate processing (step 1) is stored in the storage medium 202B, and the substrate processing is executed based on such a program. The program may be inputted from the communicating unit 202E or an input unit 202C.

In the process of the step 1, since the processing gas is supplied while the target substrate W is maintained at the low temperature (first temperature), sublimation of the metal-organic compound complex formed on the metal layer of the target substrate is suppressed. Accordingly, adherence of metal to the inner wall surface of the processing vessel 101 due to the sublimation of the metal-organic compound complex is suppressed.

Further, the first temperature is preferably set to be equal to the temperature at which the vapor pressure of the formed metal-organic compound complex becomes lower than the pressure inside the first processing space 101A, whereby the sublimation of the metal-organic compound complex can be suppressed more effectively.

In the process of the step 1, the processing gas is not limited to the formic acid, but another organic compound having the same chemical reactivity as that of the formic acid can be used instead.

As an example of the organic compound available as the processing gas, carboxylic acid, carboxylic anhydride, ester, alcohol, aldehyde, ketone, or the like can be utilized.

Carboxylic acid is a material containing at least one carboxylic group. Specifically, exemplary carboxylic acids may include a compound of formula R¹—COOH (R¹ is a hydrogen atom, a hydrocarbon group, or a functional group wherein at least one of hydrogen atoms of the hydrocarbon group is substituted with a halogen atom), or a polycarboxylic acid. An alkyl group, an alkenyl group, an alkynyl group, an aryl group, or the like can be an example of the hydrocarbon group, and fluorine, chlorine, bromine or iodine can be an example of the halogen atom.

The carboxylic acid can be formic acid, acetic acid, propionic acid, butyric acid, valeric acid, 2-ethyl hexanoic acid, trifluoro acetic acid, oxalic acid, malonic acid, citric acid, or the like.

A general carboxylic anhydride can be expressed by a formula R²—CO—O—CO—R³ (R² and R³ are hydrogen atoms, hydrocarbon groups, or functional groups in which at least one of hydrogen atoms constituting the hydrocarbon groups is substituted with a halogen atom). Properties of the R² and R³ are the same as those of the R¹ of the carboxylic acid.

The carboxylic anhydride can be an acetic anhydride, formic anhydride, propionic anhydride, acetic-formic anhydride, butyric anhydride, valeric anhydride, or the like.

General ester can be expressed by a formula R⁴—COO—R⁵ (R⁴ is a hydrogen atom, a hydrocarbon group, or a functional group in which at least one of hydrogen atoms constituting the hydrocarbon group is substituted with a halogen atom, and R⁵ is a hydrocarbon group, or a functional group in which at least one of hydrogen atoms constituting the hydrocarbon group is substituted with a halogen atom). Properties of the R⁴ are the same as those of the R¹ of the carboxylic acid, and properties of the R⁵ are the same as those of the R¹ of the carboxylic acid (except hydrogen atoms).

The ester may be, for example, a methyl formate, ethyl formate, propyl formate, butyl formate, benzyl formate, methyl acetate, ethyl acetate, n-propyl acetate, n-butyl acetate, pentyl acetate, hexyl acetate, octyl acetate, phenyl acetate, benzyl acetate, aryl acetate, propenyl acetate, methyl propionate, ethyl propionate, butyl propionate, pentyl propionate, benzyl propionate, methyl butyrate, ethyl butyrate, pentyl butyrate, butyl butyrate, methyl valerate, ethyl valerate, or the like.

Alcohol is a material containing at least one alcohol group. Specifically, it can be a compound expressed by a formula R⁶—OH(R⁶ is a hydrocarbon group, or a functional group obtained by substituting at least one of hydrogen atoms constituting the hydrocarbon group with a halogen atom), polyhydroxy alcohol such as diol and triol or the like. Properties of the R⁶ are the same as those of the R¹ of the carboxylic acid (except hydrogen atoms).

The alcohol may be methanol, ethanol, 1-propanol, 1-butanol, 2-methyl propanol, 2-methyl butanol, 2-propanol, 2-butanol, t-butanol, benzyl alcohol, o-, p- and m-cresol, resorcinol, 2,2,2-trifluoro ethanol, ethylene glycol, glycerol, or the like.

Aldehyde is a material containing at least one aldehyde group. Specifically, it can be a compound expressed by a formula R⁷—CHO(R⁷ is a hydrocarbon group, or a functional group obtained by substituting at least one of hydrogen atoms constituting the hydrocarbon group with halogen atoms), Alkanediol compound, or the like. Properties of the R⁷ are the same as those of the R¹ of the carboxylic acid.

The aldehyde may be formaldehyde, acetaldehyde, propionaldehyde, butylaldehyde, glyoxal, or the like.

General ketone can be expressed by a formula R⁸—CO—R⁹ (R⁸ and R⁹ are hydrocarbon groups, or functional groups obtained by substituting at least one of hydrogen atoms constituting the hydrocarbon groups with halogen atoms). Further, as one kind of ketone, there is diketone capable of being expressed by a formula R¹⁰—CO—R¹¹—CO—R¹² (R¹⁰, R¹¹ and R¹² are hydrocarbon groups, or functional groups obtained by substituting at least one of hydrogen atoms constituting the hydrocarbon groups with halogen atoms).

The ketone or diketone may be acetone, dimethyl ketone, diethyl ketone, 1,1,1,5,5,5-hexafluoroacetyl acetone, or the like.

Now, a second processing unit which performs a process of step 2 after the process of the step 1 by the first processing unit 100 will be explained.

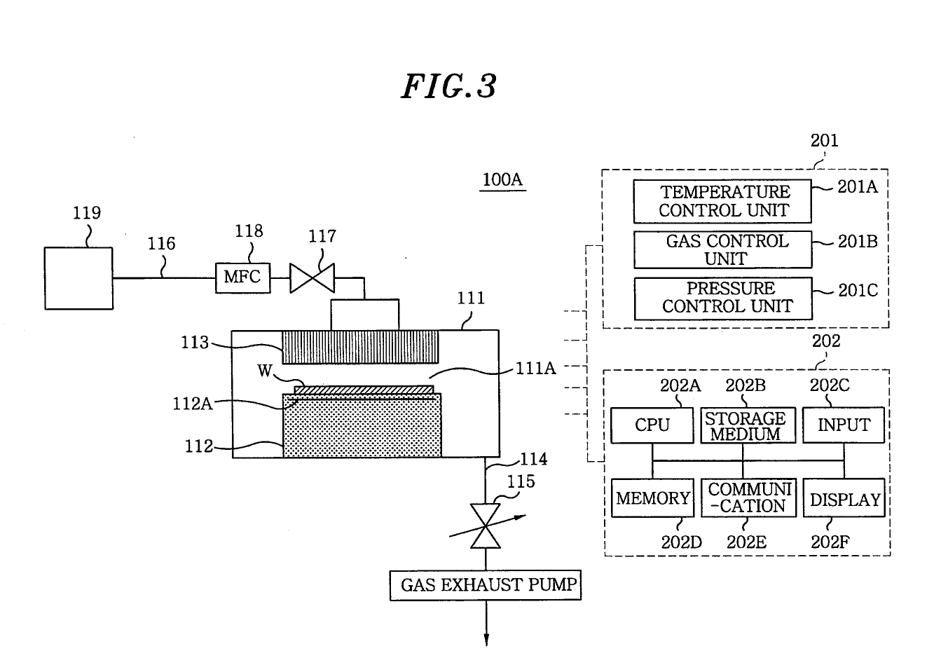

FIG. 3 illustrates a second processing unit 100A that is a part of the cluster substrate processing apparatus, like the first processing unit 100 shown in FIG. 1. In the second processing unit 100A, the step 2 of FIG. 1 is performed.

Referring to FIG. 3, the second processing unit 101A includes therein a processing vessel 111 which defines a second processing space 111A, and a supporting table 112 for supporting the target substrate W thereon is installed in the processing space 111A.

A heating unit 112A having, e.g., a heater is embedded in the supporting table 112. The target substrate W supported on the supporting table 112 con be heated by the heating unit 112A to the second temperature higher than the first temperature of the step 1.

Further, the second processing space 111A is evacuated to vacuum via a gas exhaust line 114 connected with the processing vessel 111 and is maintained in a depressurized state. The gas exhaust line 114 is connected to a gas exhaust pump via a pressure control valve 115, so that the processing space can be maintained at a desired depressurized pressure level.

Moreover, a shower head 113 for diffusing an inert gas supplied through a processing gas supply line 116 into the second processing space 111A is provided on the side of the second processing space 111A facing the supporting table 112.

Further, a gas supply line 116 for supplying the inert gas into the shower head 113 is connected with a gas container 119 which stores an inert gas such as Ar, N₂, He or the like inside. Here, besides the Ar or He, another rare gas species (e.g., Ne, Kr, Xe or the like) can also be used as the inert gas. Further, a valve 117 and a flow rate controller (MFC) 118 for controlling the flow rate of the inert gas are installed on the gas supply line 116, whereby a control of start and stop of the supply of the inert gas and a control of the flow rate of the supplied inert gas can be carried out.

The process of the step 2 by the second processing unit 100A is carried out as follows.

First, upon the completion of the process of step 1 by the first processing unit 100, the target substrate W is transferred into the processing vessel 111 of the second processing unit 100A and is mounted on the supporting table 112.

Here, the target substrate W is heated by the heating unit 112A, whereby the temperature of the target substrate W is controlled to be maintained at the second temperature higher than the first temperature of the step 1. Accordingly, the metal-organic compound complex formed on the metal layer (metal wiring) of the target substrate W is sublimated and exhausted through the gas exhaust line 114. Further, though the inside of the second processing space 111A is maintained at the preset depressurized state (vacuum state) in the process of heating the target substrate W (sublimation of the metal-organic compound complex), it may be also possible to supply the inert gas into the second processing space through the gas supply line 116 via the shower head 113.

By performing the process of the step 1 in the first processing unit 100 and the process of the step 2 in the second processing unit 100A, the metal oxide film (e.g., the Cu oxide film) formed on the metal layer (e.g., the Cu wiring) of the target substrate can be removed.

Further, the second processing unit 100A shares the controller 201 and the computer 202 described earlier in FIG. 2 in conjunction with the first processing unit 100. Alternatively, it may be also possible to configure the substrate processing unit such that the first and the second processing unit 100 and 100A have individual controllers and computers.

The temperature control unit 201A controls the temperature of the target substrate W by means of controlling the heating unit 112A. Further, the gas control unit 201B controls the valve 117 and the flow rate controller 118 so as to control the start of the supply of the inert gas, the stop of the supply of the processing gas and the flow rate of the supplied inert gas. The pressure control unit 201C controls the degree of openness of the pressure control valve 115 to thereby control the pressure inside the second processing space 111A.

Further, the computer 202 which controls the controller 201 executes the substrate processing method for the substrate processing (step 2) in the second processing unit 100A based on a program stored in the storage medium 202B.

In the process of the step 2, it is characterized in that the target substrate W is heated to the high temperature (second temperature) in the second processing space 111A into which no processing gas is supplied, whereby the metal-organic compound complex is sublimated. Thus, even when metal is adhered to the inner wall surface of the processing vessel 111 or the supporting table 112, reattachment of the metal to the target substrate as a result of etching by the processing gas can be suppressed.

Further, if chamber cleaning of the processing vessel (supporting table), in which the substrate processing is carried out, is performed, the inside of the processing vessel can be kept clean, and it becomes possible to perform a stable substrate processing regardless of history of the substrate processing performed therein. As for a processing temperature at this time, the temperature of the inner wall surface of the processing vessel 111 or the temperature of the supporting table 112 is preferably set to be higher (for example, about 400° C. or higher) than the second temperature for the substrate processing so as to sublimate the metal complex adhered to the inner wall surface of the processing vessel 111 or the supporting table 112.

For example, the metal attached to the inside of the processing vessel 111 such as the inner wall surface of the processing vessel 111 or the supporting table 112 can be removed as follows, if necessary.

In the state the target substrate w is not accommodated in the processing vessel 111, the supply of the processing gas into the processing vessel 111 is stopped. Then, to sublimate the metal deposit attached to the inside of the processing vessel, the inside of the processing vessel 111 (e.g., the inner wall surface of the processing vessel 111 or the supporting table 112) to which the metal is attached is heated at a temperature higher than the temperature at which the processing of the target substrate is performed, and the pressure inside the processing vessel 111A is controlled to be maintained at a lower pressure (e.g., no greater than about 1×10⁻⁵ Pa, preferably no greater than about 1×10⁻⁶ Pa, and more preferably no greater than about 1×10⁻⁷ Pa), so that the metal deposit is removed.

To control the pressure inside the processing space 111A at such a low pressure level, it may be preferable to use, for example, a turbo molecular pump, a cryopump and a dry pump in combination. Further, the temperature to which the inside of the processing vessel 111 having the metal deposit is heated is preferably set to be of a level at which the vapor pressure of the metal deposit becomes higher than the pressure inside the processing space 111A, so that the metal deposit can be more effectively removed.

Further, in case that the amount of the metal adhered on the top surface of the supporting table 112 is large, the metal deposit can be removed as follows. A thin plate shaped susceptor is installed on the top surface of the supporting table 112 so as to cover the supporting table, and the substrate processing is performed while maintaining the target substrate on the susceptor. In this configuration, the metal adheres not to the top surface of the supporting table but to the top surface of the susceptor. Then, it may be possible to unload the susceptor from the processing vessel 111 and load it into a separate vessel by a transfer device and then to sublimate the metal deposit on the susceptor in the separate vessel.

Accordingly, wiring, interlayer insulating films and the like formed on the target substrate can be suppressed from being contaminated due to reattachment of the metal, and clean substrate processing can be performed. Therefore, it becomes possible to manufacture a semiconductor device having Cu wiring by carrying out, e.g., removal of an oxide film of the Cu wiring in a cleanly manner by using an organic compound gas, while suppressing an influence from contamination due to reattachment of Cu.

Further, though the above description has been provided for an exemplary case of using the heater as the heating unit for heating the target substrates W, the heating unit is not limited thereto. For instance, the heating unit can be implemented by a method of forming a flow path in the supporting table 112 and circulating a heat exchange fluid through the flow path, as in the case of the first processing unit 100.

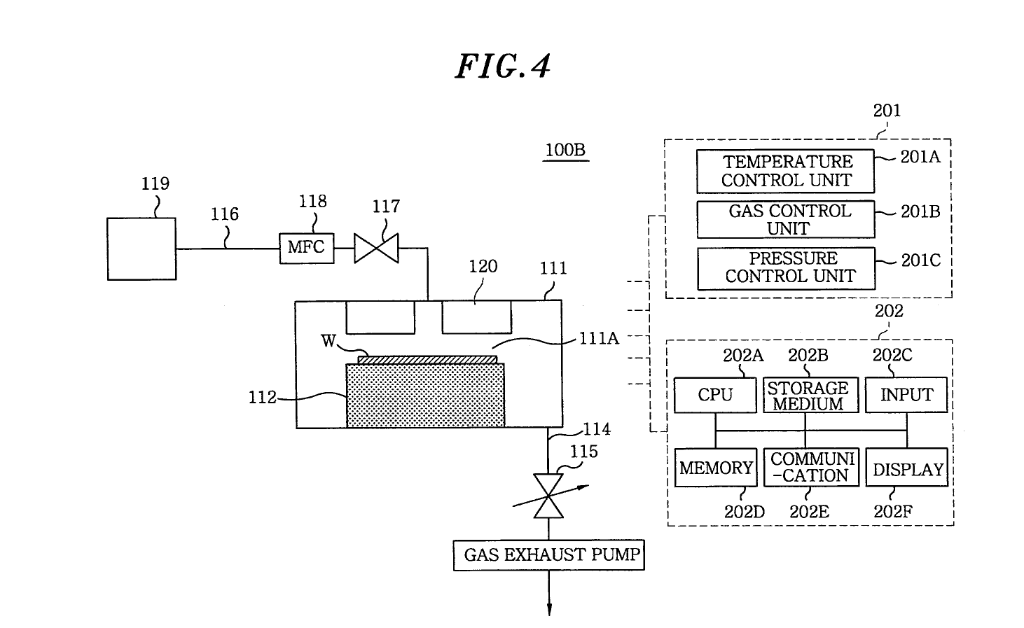

Alternatively, a method using a UV (Ultraviolet) lamp may also be employed as the heating unit of the target substrate, as illustrated in FIG. 4.

FIG. 4 illustrates a second processing unit 100B which is a modification example of the second processing unit 100A shown in FIG. 3. Here, like reference numerals will be used for like parts identical to those described in FIG. 3, and redundant description thereof will be omitted.

Referring to FIG. 4, a heating unit 120 made up of a UV lamp for heating the target substrate W is installed at a position facing the supporting table 112 in the processing vessel 112. When performing the process of the step 2 by using the second processing unit 100B, the target substrate is heated by irradiating UV rays to the target substrate W by the heating unit 120.

If the heating of the target substrate is conducted through the irradiation of the UV rays as stated above, a time period needed to raise the temperature of the target substrate to the second temperature can be shortened, and substrate processing efficiency can be improved. Moreover, in comparison with heating via the supporting table, a cooling rate of the target substrate is faster after the completion of the process (after stopping the irradiation of the UV rays). Thus, when repeating temperature rise and fall by, for example, repeating the processes of the steps 1 and 2, processing efficiency can be improved by heating the target substrate by means of the irradiation of the UV rays.

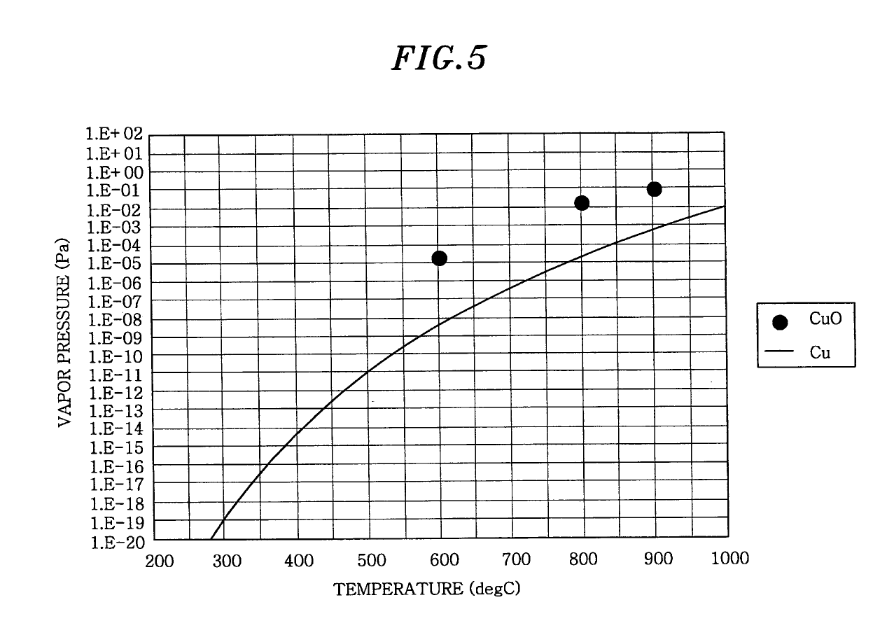

Meanwhile, vapor pressures of solid Cu and CuO are specified in Non-patent Documents 1 and 2, and the result of comparing these vapor pressures is provided in FIG. 5.

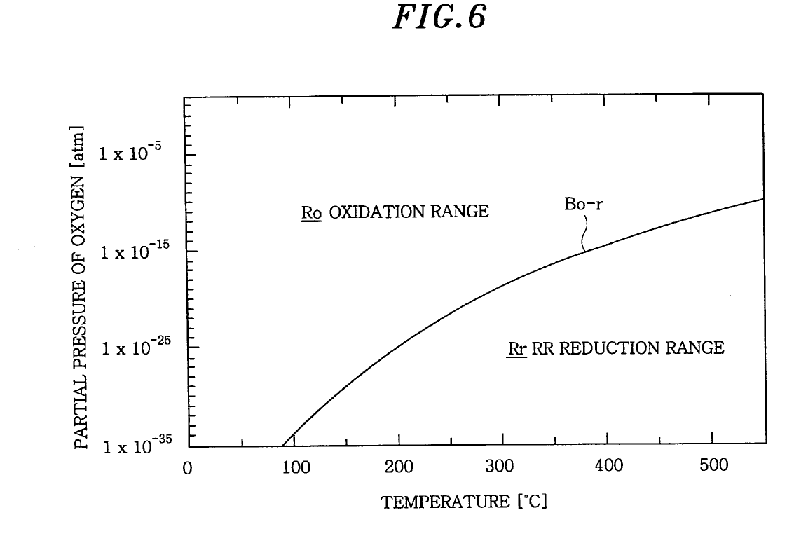

As can be seen from FIG. 5, the vapor pressure of the copper oxide is higher than the vapor pressure of the metal copper. Meanwhile, according to Patent Document 2, equilibrium oxygen concentration of CuO is described as in FIG. 6, and it discloses that if temperature and partial pressure of oxygen are set to fall within a reduction range Rr below an equilibrium oxygen concentration curve Bo-r, CuO reduces.

Accordingly, in case that the metal adhered to the inner wall surface of the processing vessel 111 and the supporting table 112 is Cu, the copper can be efficiently removed by heating the inner wall surface of the processing vessel 111 or the supporting table 112 under a high vacuum atmosphere (but under an atmosphere of oxygen partial pressure higher than the equilibrium oxygen concentration curve of FIG. 6) after oxidizing the metal Cu.

For example, the copper adhered to the processing vessel or the supporting table can be oxidized by supplying an oxidizing gas containing oxygen such as O₂, O₃, N₂O, CO₂, or the like into the processing vessel and then heating copper-adhered places at a temperature equal to at least 100° C. or above about 100° C.

Further, for any metal other than Cu, in case that the vapor pressure of a metal oxide thereof is higher than the vapor pressure of the metal, it is possible to remove the metal efficiently by heating the inner wall surface of the processing vessel 111 or the supporting table 112 under the high vacuum atmosphere after oxidizing the metal, as in the case of Cu.

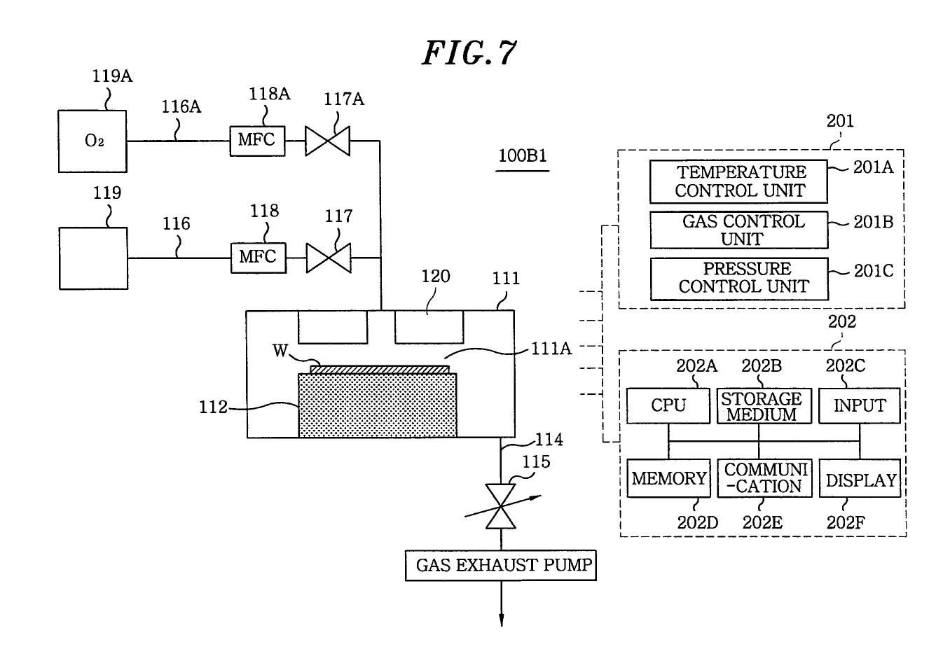

FIG. 7 shows a configuration of an apparatus example 100B1 in case of using O₂ as the oxidizing gas for oxidizing the metal adhered on the inner wall surface of the processing vessel or the supporting table.

Referring to FIG. 7, though the apparatus example 100B1 has the same configuration as that of the apparatus 100B shown in FIG. 4 in that it includes a gas container 119, a gas supply line 116, a flow rate controller 118 and a valve 117, it further includes an oxygen supply unit having an oxygen gas source 119A, an oxygen supply line 116A, a flow rate controller 118A and a valve 117A. With this configuration, by supplying an oxygen gas into the processing vessel 111, a metal such as Cu attached to the processing vessel or the supporting table can be oxidized.

Now, a third processing unit, which performs a process of step 3 subsequently of the process of step 2 by the second processing unit 100A or 100B, will be explained.

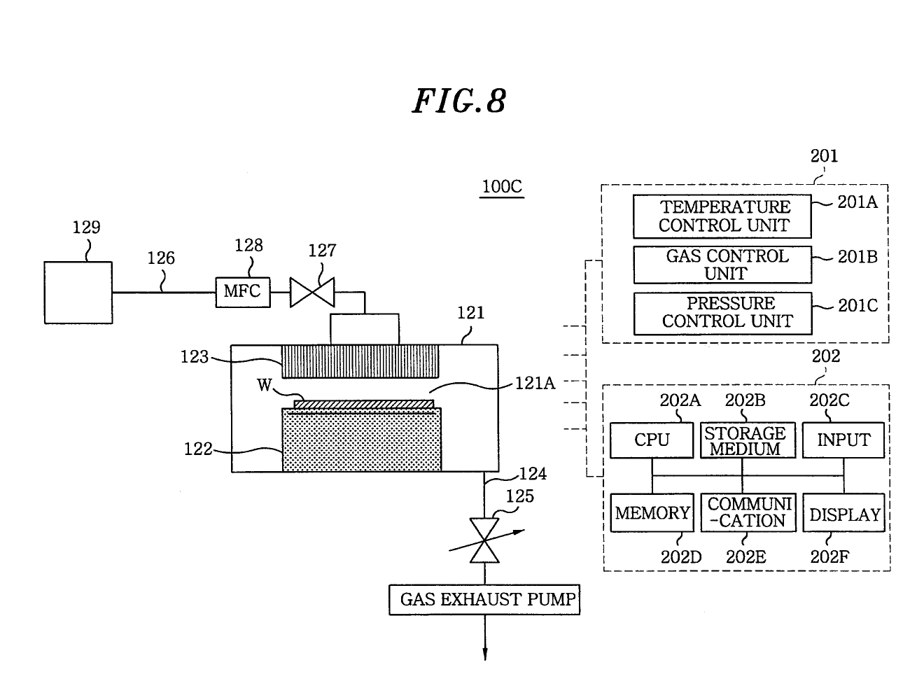

FIG. 8 illustrates a third processing unit 100C, a part of the cluster substrate processing apparatus. In the third processing unit 100C, the step 3 shown in FIG. 1 is performed.

Referring to FIG. 8, the basic configuration of the third processing unit 100C is identical with that of the second processing unit 100A shown in FIG. 3. A processing vessel 121, a third processing space 121A, a supporting table 122, a shower head 123, a gas exhaust line 124, a pressure control valve 125, a gas supply line 126, a valve 127, a flow rate controller 128 and a gas container 129 shown in this figure correspond to the processing vessel 111, the second processing space 111A, the supporting table 112, the shower head 113, the gas exhaust line 114, the pressure control valve 115, the gas supply line 116, the valve 117, the flow rate controller 118 and the gas container 119 of the second processing unit 100A shown in FIG. 3, and they have the same configurations and functions as those of their correspondent components.

Further, the third processing unit 100C shares the aforementioned controller 201 and computer 202 with the first processing unit 100 and the second processing unit 100A (or 100B). Alternatively, it is preferable that the substrate processing apparatus can be configured such that the first processing unit 100, the second processing unit 100A and the third processing unit 100C have their own controllers and computers individually.

The controller 201 and the computer 202 control and operate the third processing unit 100C, as in the case of the second processing unit 100A.

The process of the step 3 in the third processing unit 100C is performed as follows. First, after the completion of the process of the step 2 by the second processing unit 100A or 100B, the target substrate W is loaded into the processing vessel 121 of the third processing unit 100C and mounted on the supporting table 122.

Here, an inert gas is supplied through the gas supply line 126 into the third processing space via the shower head 123. The supplied inert gas reaches the target substrate W, and cools the target substrate W which has been heated in the step 2.

Further, though the method of supplying the inert gas is adopted as a cooling method in the third processing unit 100C, the cooling method is not limited thereto. For example, as in the case of the first processing unit 100, it may be possible to provide a cooling unit (flow path) in the supporting table 122 and circulate a cooling medium therethrough. Further, in such case, an electrostatic attraction structure may be provided at the supporting table 122, and a method of controlling cooling amount by an attracting force for the target substrate can also be employed in combination.

Moreover, the cooling of the target substrate after the completion of the step 2 may be carried out in the second processing unit 100A or 100B. Further, in case that the steps 1 and 2 are repeated, the cooling of the target substrate may be performed in the first processing unit 100. In such cases, the third processing unit 100C (step 3) can be omitted. Meanwhile, the use of the third processing unit 100C (step 3) enables an enhancement of the cooling rate of the target substrate and an improvement of processing efficiency thereof.

Hereinafter, an example of the entire configuration of the cluster substrate processing apparatus having the above-described first, second and third processing units 100, 100A and 100C will be explained.

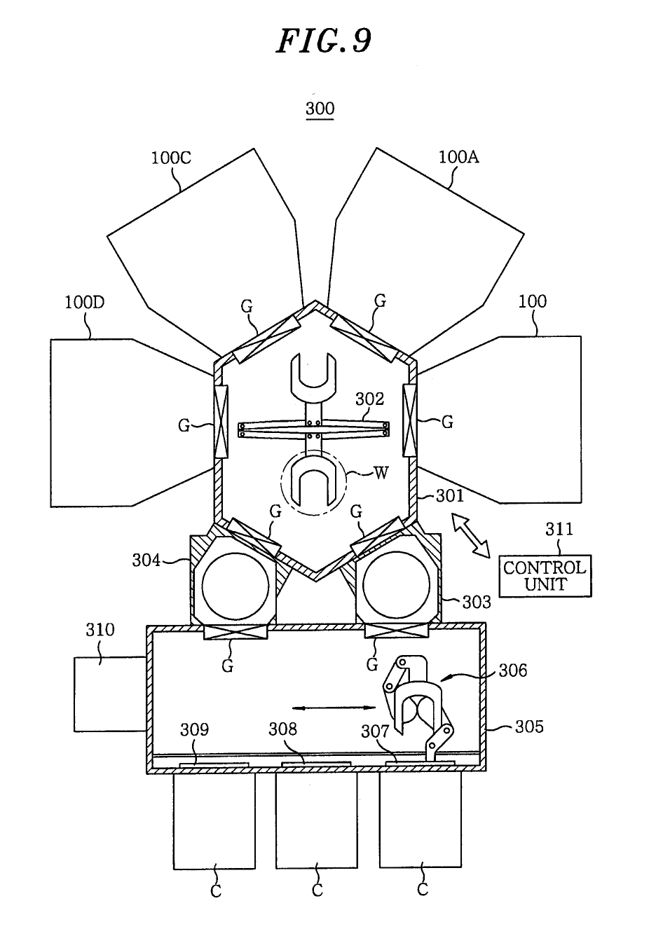

FIG. 9 is a plane view schematically illustrating the configuration of a cluster substrate processing apparatus 300 including the above-described first, second and third processing units 100, 100A and 100C.

Referring to FIG. 9, the substrate processing apparatus 300 schematically illustrated in this figure has a configuration in which the first processing unit 100 (processing vessel 101), the second processing unit 100A (processing vessel 111), the third processing unit 100C (processing vessel 121) and a fourth processing unit 100D (to be described later) are commonly connected to a transfer chamber 301 whose inside is set under a depressurized state or an inert gas atmosphere.

The transfer chamber 301 has a hexagonal shape when viewed from the top thereof, and the first processing unit 100, the second processing unit 100A, the third processing unit 100C and the fourth processing unit 100D are respectively connected to corresponding sides of the hexagonal transfer chamber so as to communicate therewith. Further, a transfer arm 302 configured to be rotatable and extensible/contractible is installed inside the transfer chamber 301. The target substrate W is transferred between the processing vessels by the transfer arm 302.

Further, load lock chambers 303 and 304 are connected to remaining two sides of the transfer chamber 301, and a substrate loading/unloading chamber 305 is connected to other sides of the load lock chambers 303 and 304, wherein the other sides oppositely face the sides thereof to which the transfer chamber 301 is connected. The substrate loading/unloading chamber 305 has three ports 307, 308 and 309 for mounting thereon carriers C capable of accommodating target substrates W. Further, provided at a lateral side of the substrate loading/unloading chamber 305 is an alignment chamber 310 in which alignment of the target substrate W is carried out.

Further, installed inside the substrate loading/unloading chamber 305 is a transfer arm 306 for performing loading/unloading of the target substrate W with respect to the carriers C and the load lock chambers 303 and 304. The transfer arm 306 has a multi-joint arm structure and carries out the transfer of the target substrate W while mounting the target substrate W thereon.

The first processing unit 100, the second processing unit 100A, the third processing unit 100C and the load lock chambers 303 and 304 are connected to the respective sides of the transfer chamber 301 via gate valves G so that the processing units or the load lock chambers are allowed to communicate with the transfer chamber 301 when the gate valves G are opened while they are isolated from the transfer chamber 301 when the gate valves G are closed. Further, gate valves G are also provided at portions where the load lock chambers 303 and 304 make connection with the substrate loading/unloading chamber 305.

The transfer operation of the target substrate W is controlled by a controller 311. The controller 311 is connected with the computer 202 previously described in FIGS. 2 to 8 (here, illustration of connection wiring therebetween is omitted). The substrate processing operation (transfer operation of the target substrate W) of the substrate processing apparatus 300 is executed by a program stored in the storage medium 202B of the computer 202.

Substrate processing in the substrate processing apparatus 300 is performed as follows. First, a target substrate W provided with a Cu wiring having a copper oxide film formed on a surface thereof is taken out of one of the carriers C and is loaded into the load lock chamber 303 by the transfer arm 306. Then, the target substrate W is transferred from the load lock chamber 303 into the first processing unit 100 (first processing space 101A) via the transfer chamber 301 by the transfer arm 302. In the first processing unit 100, the above-described process of step 1 is performed, and a processing gas (formic acid or the like) is adsorbed to the Cu wiring, so that a metal-organic complex is formed on the surface of the Cu wiring.

Thereafter, the target substrate W is transferred from the first processing unit 100 into the second processing unit 100A (second processing space 111A) by the transfer arm 302. In the second processing unit 100A, the above-stated process of step 2 is conducted, so that the metal-organic complex on the surface of the Cu wiring is sublimated.

Subsequently, the target substrate W is transferred from the second processing unit 100A into the third processing unit 100C (third processing space 121A) by the transfer arm 302. In the third processing unit 100C, the above-described process of step 3 is conducted, so that the target substrate W is cooled.

The target substrate W which has undergone the processes of steps 1 to 3 is transferred into the load lock chamber 304 by the transfer arm 302 and then is transferred from the load lock chamber 304 into a predetermined carrier C via the transfer arm 306. By repeating these series of processes on each of target substrates W accommodated in a carrier C in sequence, the target substrates can be consecutively processed.

By using the substrate processing apparatus 300, oxidization of the Cu wiring due to the exposure of the target substrate W to oxygen or adherence of contaminants to the target substrate W can be suppressed, and the substrate processing can be carried out in a clean environment. Furthermore, since the first processing space 101A, in which the processing gas is supplied and the metal-organic compound complex is formed, and the second processing space 111A, in which no processing gas is supplied and the metal-organic compound complex is sublimated, are separated from each other, reattachment of metal can be more effectively suppressed.

Further, it may be also possible to configure the substrate processing apparatus so as to perform the processes of steps 1 and 2 or the processes of steps 1 to 3 in the same processing vessel (processing space). In such case, the substrate processing apparatus can be simplified and costs for the substrate processing (semiconductor manufacture) can be reduced. In such configuration, it may be preferable to dispose a temperature control mechanism including a cooling unit, a heating unit and the like in the one same processing unit (processing vessel) and to supply both the processing gas and the inert gas into it.

Even in case of performing the processes of steps 1 and 2 or steps 1 to 3 in the same processing vessel, the substrate processing can be realized in a cleaner environment in which the reattachment of the metal is suppressed, in comparison with the conventional substrate processing method (i.e., the method of performing the formation and the sublimation of the metal-organic compound complex together.

Moreover, in the above-stated substrate processing apparatus 300, the step 1 and the step 2 can be repeated by alternately transferring the target substrate W into the first processing unit 100 and the second processing unit 100A. In such case, the oxide film on the metal layer can be removed efficiently. Further, it may be also possible to transfer the target substrate W to the third processing unit 100C (i.e., to add the process of step 3) if necessary.

In addition, it may be also possible to transfer the target substrate W into the fourth processing unit 100D after the completion of the process (step 2) in the second processing unit 100A or the process (step 3) in the third processing unit) and have substrate processing to be performed therein. For example, the substrate processing apparatus can be configured such that a film formation of a Cu diffusion barrier film is performed in the fourth processing unit 100D.

Further, the shape of the transfer chamber 301 is not limited to the hexagonal shape but can be modified so that more processing units (processing chambers) can be connected thereto. For instance, a processing unit (processing vessel) for performing a film formation of a metal film or an insulating layer (interlayer insulating film) can be additionally connected to the transfer chamber so that the formation of the metal film or the interlayer insulating film can be conducted immediately after the formation of the Cu diffusion barrier film.

### Second Embodiment

A Cu oxide film is removed by performing a substrate processing in accordance with the above-described substrate processing method and an analysis on the removal result is explained hereinafter. Here, a specific example of removing the Cu oxide film for the first time will be described.

First, vaporized formic acid (processing gas) was supplied to a target substrate having Cu whose surface had been oxidized. The formic acid was adsorbed in the surface of the Cu, so that a metal complex (metal-organic compound complex) was formed. The adsorption of the formic acid was checked by a degas analysis of the target substrate. In this example, the internal pressure of a processing space accommodating the target substrate therein was set to be maintained within a range from about 0.4 to 0.7 kPa, and the temperature of the target substrate was maintained substantially at a room temperature (step 1).

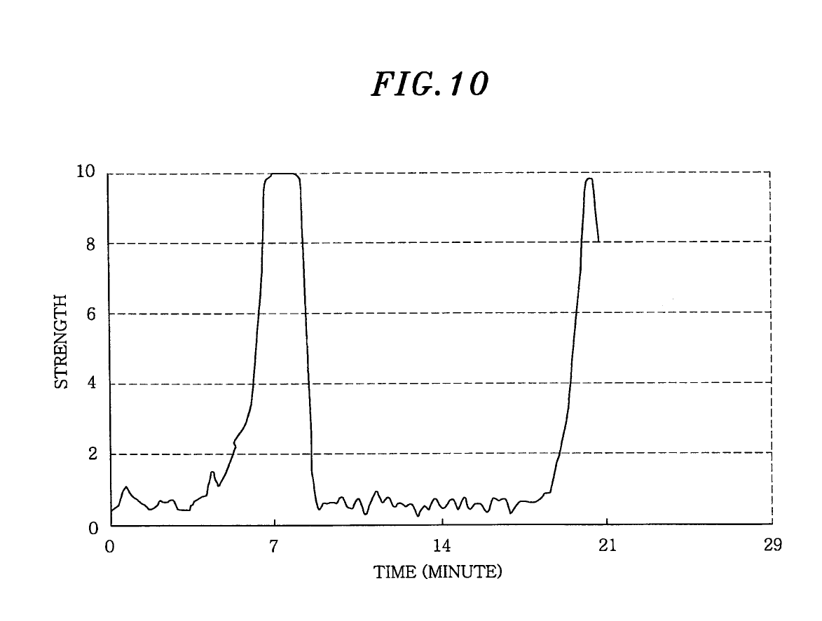

Then, the target substrate was heated in a processing space maintained in a depressurized state where a pressure was equal to or lower than about 1×10⁻⁵ Pa, and reaction products including the metal-organic compound complex was sublimated (step 2). Here, analysis of gas (sublimation) in the processing space was conducted by using a mass spectrometer, and the result is provided in FIG. 10.

FIG. 10 is a chart showing the gas analysis result that contains a detection result of Cu (63 amu). A horizontal axis represents heating time and a vertical axis indicates detection strength (in an arbitrary unit).

As can be seen from FIG. 10, Cu was detected at time points of about 7 minutes and 20 minutes after the initiation of the heating. The temperature of the target substrate at the time point of 7 minutes after the start of heating was about 150° C., and the temperature of the target substrate at the time point of about 20 minutes after the start of the heating was higher than at least 400° C. In comparison, when heating a target substrate having Cu for which no formic acid (processing gas) was supplied, Cu was also detected at the time point of about 20 minutes, although no Cu was detected at the time point of 7 minutes in this case. Accordingly, the Cu detected at the time point of about 7 minutes (about 150° C.) after the start of the heating is deemed to be originated from the vaporized metal complex. That is, it has been found that the target substrate desirably needs to be heated at a temperature equal to or higher than 150° C. to sublimate the metal complex.

The vapor pressure of the metal complex may be at least about 1×10⁻⁵ Pa at about 150° C. Further, it also has been found that the metal (Cu), not the metal complex, needs to be heated at the temperature higher than at least 400° C. to be sublimated. The vapor pressure of the metal (Cu), not the metal complex, cannot be increased to 1×10⁻⁵ Pa or higher unless the temperature is set to be no smaller than at least 400° C. Further, the temperature rising rate is not limited to the aforementioned example, but it can be set to be higher.

Now, a result of thickness measurement of the removed copper oxide film will be described. FIG. 11 shows a relationship between a thickness of the copper oxide film before the processing obtained based on a phase difference Ad (horizontal axis) measured by an ellipsometry method (wavelength 633 nm) and a value (vertical axis) corresponding to the amount of the removed copper oxide film estimated based on a detection amount of the Cu. In the measurement by the ellipsometry method, since the thickness of the copper oxide film is largely manifested by a variation of the phase difference Ad, the horizontal axis corresponds to the thickness of the copper oxide film before the processing.

As can be seen from FIG. 11, the amount of the removed copper oxide film (Cu equivalent amount) increases in proportion to the thickness of the formed copper oxide film, thereby confirming that the copper oxide film can be removed through the above-described substrate processing process. For example, when converted into the phase difference Ad, the natural oxide film formed on the Cu is observed at about 10° and its amount is about 4 nm, it can be easily removed by the above-stated substrate processing method.

Further, the amount of the removed copper oxide film tends to be converged as the thickness of the formed copper oxide film increases. Thus, in the event that the thickness of the copper oxide film to be removed is great, the copper oxide film can be removed effectively by repeating the steps 1 and 2 (or steps 1 to 3).

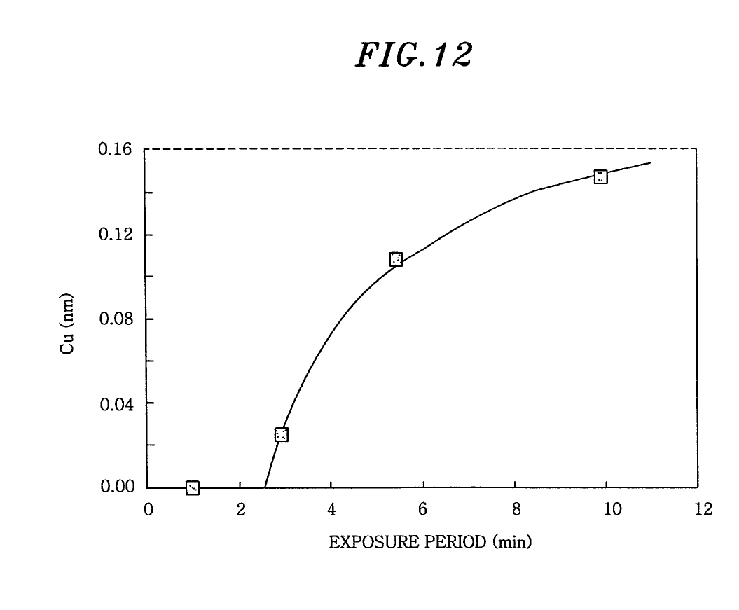

Further, in FIG. 12, a horizontal axis represents a processing time of the step 1 (exposure period of Cu to the processing gas), and a vertical axis indicates a removed thickness of the copper oxide film (Cu equivalent thickness).

As can be seen from FIG. 12, the removed amount of the copper oxide film (Cu equivalent amount) tends to increase in proportion of the processing time (exposure period) of the step 1. Furthermore, in order to improve processing efficiency, the adsorption amount of the processing gas can be increased by lowering the cooling temperature (first temperature in the step 1) of the target substrate, so that the thickness of the removable copper oxide film can be increased, as in the case of increasing the exposure period.

### Third Embodiment

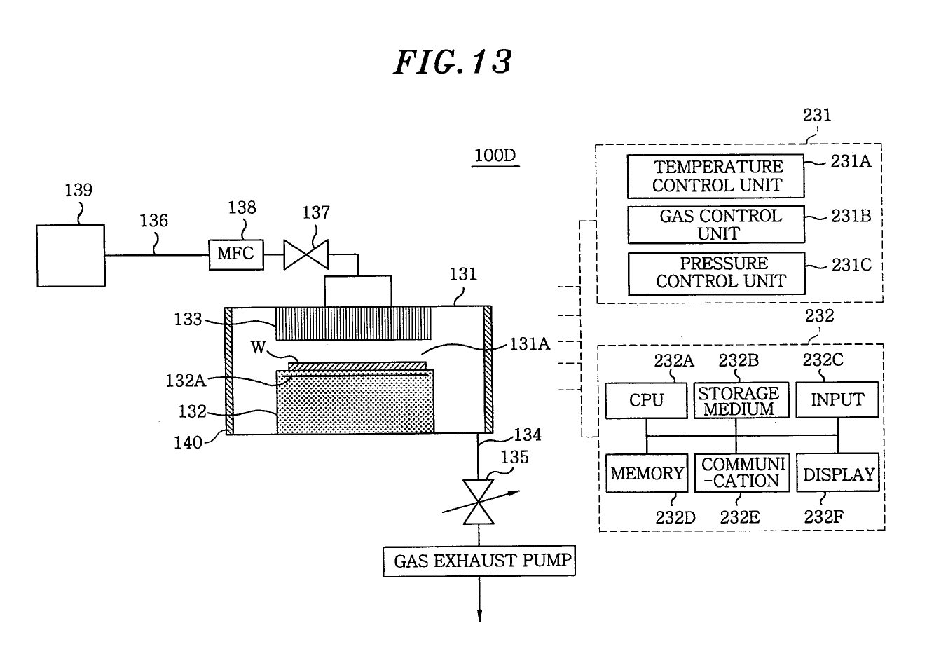

Hereinafter, an example of the processing unit 100D, which is a processing unit (substrate processing apparatus) capable of performing the conventional substrate processing method (i.e., the method of performing the formation and the sublimation of the metal-organic compound complex together) and capable of removing metal deposits attached to the inside thereof, will be explained with reference to FIG. 13. Like the processing chamber 100 (100A to 100C) described earlier, the processing chamber 100D functions as a part of the cluster substrate processing apparatus and is used by being connected to the transfer chamber 301, for example.

As shown in FIG. 13, the processing unit 100D includes a processing vessel 131 having a processing space 131A therein, and a supporting table 132 for sustaining a target substrate W thereon is installed in the processing space 131A.

A heating unit 132A made up of, e.g., a heater is embedded in the supporting table 132. The target substrate W sustained on the supporting table 132 is heated by the heating unit 132A together with the supporting table 132. Further, another heating unit 140 made up of, e.g., a heater is also installed in the processing vessel 131 to heat the inner wall surface (a portion to which metal adheres) of the processing vessel 131.

Further, the processing space 131A is evacuated to vacuum via a gas exhaust line 134 connected with the processing vessel 131 and is maintained in a depressurized state. The gas exhaust line 134 is connected to a gas exhaust pump via a pressure control valve 135, so that the processing space 131A can be kept under the depressurized state of a desired pressure level. In addition, it may be also possible to dispose a receptacle for recollecting exhausted organic compound at the rear end of the gas exhaust pump and to recycle the recollected organic compound.

Moreover, a shower head 133 for diffusing a processing gas supplied through a processing gas supply line 136 into the processing space 131A is provided on one side of the processing space 131A facing the supporting table 102, and is configured to diffuse the processing gas onto the target substrate W uniformly.

Further, the processing gas supply line 136 for supplying the processing gas into the shower head 133 is connected with a source container 139 which accommodates a liquid or solid source material 130 inside. Further, a valve 137 and a flow rate controller (e.g., a mass flow controller called a MFC in short) 138 for controlling the flow rate of the processing gas are installed on the processing gas supply line 136, whereby start and stop of the supply of the processing gas and the f low rate of the supplied processing gas can be controlled.

For example, the source material 130 is made of an organic compound such as formic acid or the like and is vaporized or sublimated in the source container 139. For instance, as for the formic acid, the formic acid is liquid at a room temperature and a certain amount of it is vaporized at the room temperature. It may be possible to stabilize the vaporization by heating the source container 139.

Further, it may be also possible to set up a configuration in which the source container 139, the processing gas supply line 136, the valve 137, the flow rate controller 138 and so forth are cooled by using a cooling medium made of, e.g., a fluorocarbon-based fluid or the like.

The processing gas provided through the processing gas supply line 136 is supplied into the processing space 131A through gas holes provided with the shower head 133. The processing gas in the first processing space 131A then reaches the target substrate W controlled (heated) to be maintained at a preset temperature (e.g., ranging from about 100° C. to 400° C.; preferably, ranging from about 150° C. to 250° C.) and is adsorbed onto the surface of a metal layer (e.g., a Cu wiring or the like), so that a metal-organic compound complex is formed. The metal-organic compound complex thus formed is immediately sublimated and removed. The formation of the metal-organic compound complex and its removal through sublimation are repeated as long as the processing gas is supplied and the metal-organic compound complex remains on the surface of the metal layer. That is, the formation and the sublimation of the metal-organic compound complex progress together.

Further, the processing efficiency for the target substrate can be improved by adding a gas other than the organic compound to the processing gas. For instance, O₂ or N₂O can be added as an oxidative gas, or H₂ or NH₃ can be added as another reductive gas.

In the above process, since the sublimated metal-organic compound complex is thermally instable, it may be easy to be decomposed in the processing space 131A, adhering to the inside of the processing vessel 131, especially, to the inner wall surface of the processing vessel 131 or the supporting table 132. Further, thus adhered metal may be re-sublimated by the processing gas, thereby being reattached to the target substrate W after all.

Now, an example of the method for removing a metal deposit adhered to the inside of the processing vessel 131 will be explained. First, the target substrate W is not accommodated in the processing vessel 131 and the supply of the processing gas into the processing vessel 131 is stopped.

Then, the inside of the processing vessel 131 (e.g., the inner wall surface of the processing vessel 131 or the supporting table 132) is heated to keep it at a temperature higher than the temperature at which the processing of the target substrate is performed, and the pressure inside the processing space 131A is controlled to be maintained at a low level (e.g., no greater than about 1×10⁻⁵ Pa, desirably no greater than about 1×10⁻⁶ Pa, and more desirably no greater than about 1×10⁻⁷ Pa) so that the metal deposit attached to the inside of the processing vessel 131 is made to sublimate, thereby achieving the removal of the metal deposit. To control the pressure inside the processing space 131A at such a low pressure level, it may be desirable to use, for example, a turbo molecular pump, a cryopump and a dry pump in combination as a gas exhaust unit.

Further, the temperature to which the inside of the processing vessel 131 having the metal deposit is heated is desirably set to be of a level at which the vapor pressure of the metal deposit becomes higher than the pressure inside the processing space 131A, whereby the removal of the metal deposit can be more effectively carried out.

Moreover, the process performed by the processing unit 100D is controlled by a computer 232 via a controller 231. The computer 232 executes the above-stated process based on a program stored in a storage medium 232B. Here, illustration of wiring of the controller 231 and the computer 232 is omitted.

The controller 231 includes a temperature control unit 231A, a gas control unit 231B and a pressure control unit 231C. The temperature control unit 231A controls the temperatures of the target substrate W and the inside of the processing vessel 131 (e.g., the inner wall surface of the processing vessel 131 and the supporting table 132) by way of controlling the heating units 132A and 140.

The gas control unit 231B executes the control of the valve 137 and the flow rate controller 138, and controls start and stop of the supply of the processing gas and the flow rate of the supplied processing gas. The pressure control unit 231C controls the degree of openness of the pressure control valve 135 to control the pressure inside the processing space 131A.

Further, the computer 232 which controls the controller 231 includes a CPU 232A, the storage medium 232B, a memory 232D, a communicating unit 232E and a display unit 232F. For example, programs of the substrate processing method and the metal deposit removing method regarding the substrate processing are stored in the storage medium 232B, and the substrate processing is executed based on such programs. The programs may be inputted from the communicating unit 232E or an input unit 232C.

In addition, the processing gas used in the above substrate processing process is not limited to the formic acid, and another organic compound having the same chemical reactivity can be utilized instead. Specifically, the same materials as described earlier as examples of organic compounds available as the processing gas in the step 1 of the first embodiment can also be used here.

Further, in case that the amount of the metal attached on the top surface of the supporting table 132 is large, the metal deposit can be removed as follows. A thin plate shaped susceptor is installed on the top surface of the supporting table 132 so as to cover the supporting table, and substrate processing is performed while maintaining the target substrate on the susceptor. In this configuration, the metal adheres not to the top surface of the supporting table 132 but to the top surface of the susceptor. Then, it may be possible to unload the susceptor from the processing vessel 131 and load it into a separate vessel again by a transfer device and then to have the metal deposit on the susceptor to sublimate in this separate vessel.

Moreover, as in the first embodiment, in case that the metal adhered to the inner wall surface of the processing vessel 131 or the supporting table 132 is Cu, the copper can be efficiently removed by heating the inner wall surface or the processing vessel 131 or the supporting table 132 under a high vacuum atmosphere (but under an atmosphere of oxygen partial pressure higher than the equilibrium oxygen concentration curve of FIG. 6) after oxidizing the metal Cu.

For example, the copper adhered to the processing vessel or the supporting table can be oxidized by supplying an oxidizing gas containing oxygen such as O₂, O₃, N₂O, CO₂, or the like into the processing vessel and then heating copper-adhered places at a temperature equal to or above about 100° C.

Further, for any metal other than Cu, in case that the vapor pressure of a metal oxide thereof is higher than the vapor pressure of the metal, it is possible to remove the metal efficiently by heating the inner wall surface of the processing vessel 131 or the supporting table 132 under the high vacuum atmosphere after oxidizing the metal, as in the case of Cu.

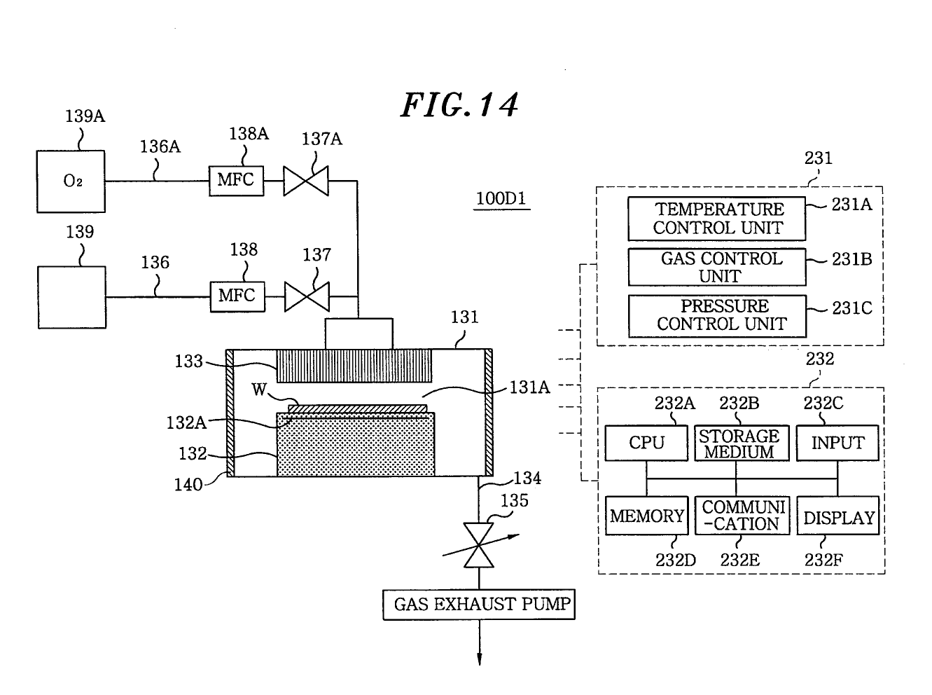

FIG. 14 illustrates a configuration of an apparatus example 100D1 in case of using O₂ as the oxidizing gas for oxidizing the metal attached on the inner wall surface of the processing vessel or the supporting table.

Referring to FIG. 14, though the apparatus example 100D1 has the same configuration as that of the apparatus example 100D described in FIG. 13, it further includes an oxygen supply unit having an oxygen gas source 139A, an oxygen supply line 136A, a flow rate controller 138A and a valve 137A. With this configuration, by supplying an oxygen gas into the processing vessel 131, a metal such as Cu attached to the processing vessel or the supporting table can be oxidized.

### Fourth Embodiment

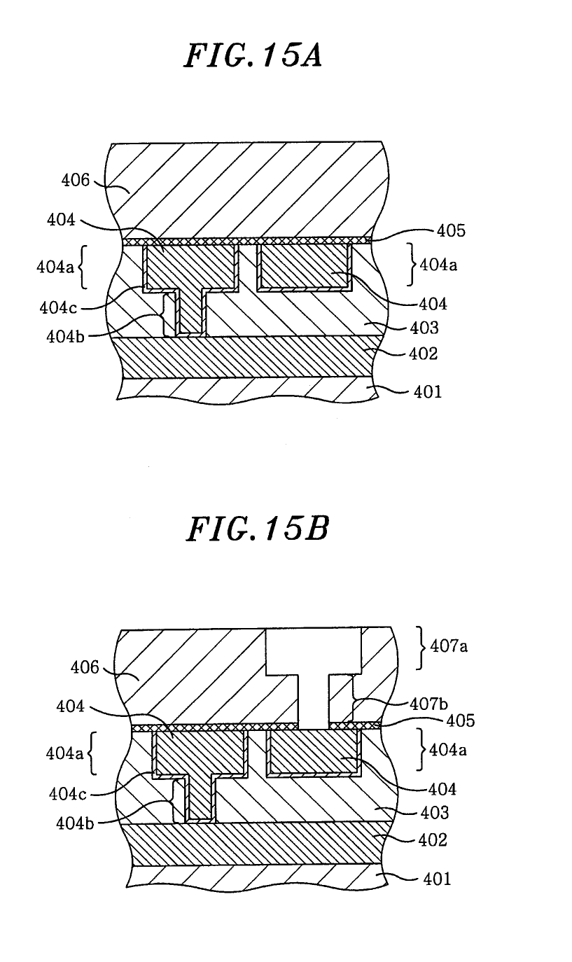

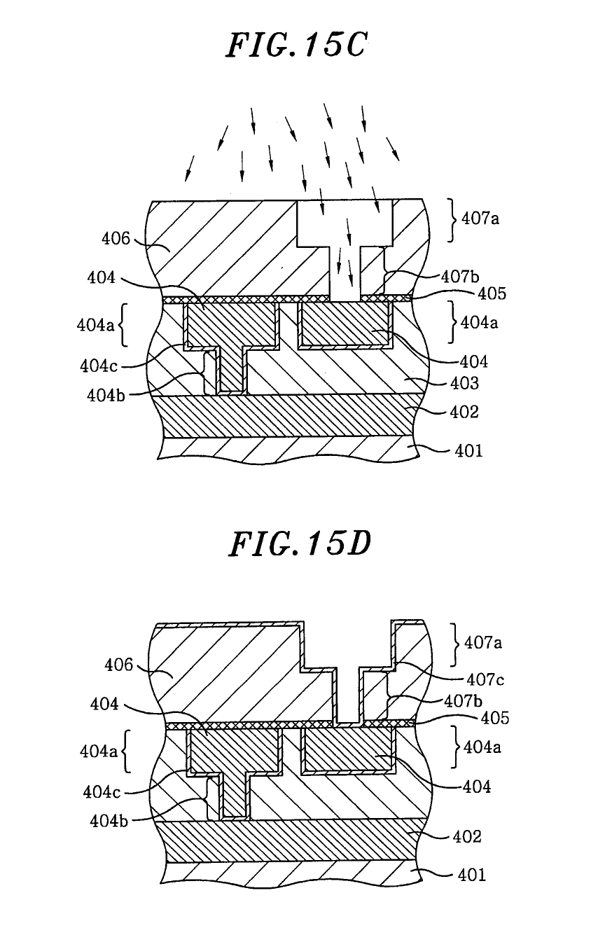

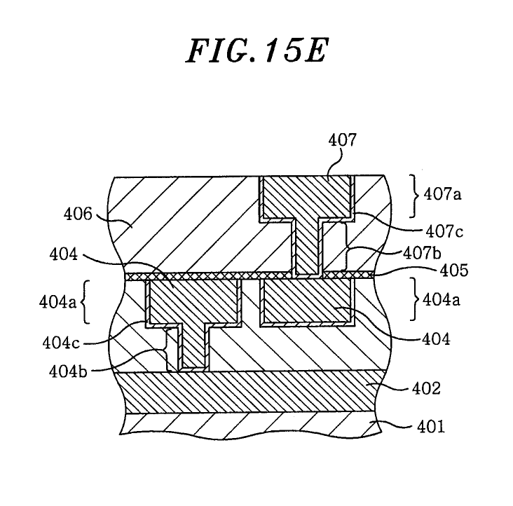

Now, a process sequence of an example method for manufacturing a semiconductor device by using the above-described substrate processing apparatus (substrate processing method) will be explained with reference to FIGS. 15A to 15E.

First, FIG. 15A illustrates an example of steps for manufacturing a semiconductor device.

Referring to FIG. 15A, in a semiconductor device in the step shown in this figure, an insulating layer 401 (e.g., a silicon oxide film) is formed to cover a device (not shown) such as a MOS transistor formed on a semiconductor substrate (corresponding to a target substrate W) made of silicon. Further, a wiring layer (not shown) made of, e.g., tungsten (W) is formed so as to be electrically connected with this device, and a wiring layer 402 made of, e.g., Cu is formed so as to be connected with this non-illustrated wiring layer.

Further, a first insulating layer (interlayer insulating film) 403 is formed on the insulating layer 401 so as to cover the wiring layer 402. A groove 404a and a hole 404b are formed in the first insulating layer 403. Wiring portions 404, each made of Cu and including a trench wiring and a via wiring, are formed in the groove 404a and the hole 404b, and they are electrically connected with the wiring layer 402 stated above.

A Cu diffusion barrier film 404c is formed between the first insulating layer 403 and the wiring portions 404. The Cu diffusion barrier film 404c functions to prevent Cu from diffusing from the wiring portions 404 into the first insulating layer 403. Furthermore, an insulating layer (Cu diffusion barrier film) 405 and a second insulating layer (interlayer insulating film) 406 are also formed to cover the wiring portions 404 and the first interlayer insulating layer 403.

Below, a method for manufacturing a semiconductor device by forming a Cu wiring by applying the above-described substrate processing method to the second insulating layer 406 will be described. Further, the wiring portions 404 can also be formed by the same method as will be described hereinafter.

In a step illustrated in FIG. 15B, a groove 407a and a hole 407b are formed in the second insulating layer 406 by applying, e.g., a dry etching method or the like. In this case, the hole 407b is formed so as to penetrate through the insulting film 405 as well. Accordingly, a part of the wiring portion 404 made of Cu is exposed through an opening formed in the second insulating layer 406. Since the surface layer of the exposed wiring portion 404 is easily oxidized, an oxide film (not shown) is formed thereon.

Then, in a step shown in FIG. 15C, removal of the oxide film of the exposed Cu wiring 404 (reduction process) is performed by using the above-described substrate processing apparatus (substrate processing method).

In this case, the target substrate W is controlled to be kept at a first temperature (e.g., a room temperature), and by supplying a processing gas (e.g., vaporized formic acid), a metal complex is formed (step 1).

Then, after stopping the supply of the processing gas, the target substrate is heated up so as to keep it at a second temperature, whereby the metal complex is sublimated (step 2). In this way, the removal of the Cu oxide film can be achieved.

Thereafter, in a step shown in FIG. 15D, a Cu diffusion barrier film 407c is formed on the second insulating layer 406 including the inner wall surfaces of the grooves 407a and 407b and on the exposed surface of the wiring portion 404. The Cu diffusion barrier film 407c is formed of, for example, a refractive metal film, a nitride film thereof, or a lamination of the refractive metal film and the nitride film thereof. For example, the Cu diffusion barrier film 407c is made of a Ta/TaN film, a WN film, a TiN film or the like, and it can be formed by employing a sputtering method, a CVD method or the like. Further, it is also possible to form the Cu diffusion barrier film 407c through a so-called ALD (Atomic Layer Deposition) method.

Next, in a step shown in FIG. 15E, a wiring portion 407 made of Cu is formed on the Cu diffusion barrier film 407c including the groove 407a and the hole 407b. In this case, the wiring portion 407 can be formed by electroplating of Cu after forming a seed layer of Cu by employing the sputtering method or CVD method, for example. The wiring portion 407 can also be formed by using the CVD method or ALD method. After forming the wiring portion 407, the surface of the substrate is flattened by applying a chemical mechanical polishing (CMP) method.

Furthermore, it is also possible to form a semiconductor device having a multilayered wiring structure by forming 2+n number (n is a natural number) of insulating layers on top of the second insulating layer 406 after a main process and then forming a wiring portion made of Cu in each of these wiring layers.

Moreover, though the present embodiment has been described for the case of forming the multi-layered wiring structure of Cu by using a dual damascene method, the present invention method can also be applied to the case of forming the multi-layered wiring structure of Cu by applying a single damascene method.

Further, though the present embodiment has been described for the Cu wiring as a metal wiring (metal layer) formed on the insulating layers, the present invention is not limited thereto. For example, the present invention can also be applied to a metal wiring (metal layer) of Ag, W, Co, Ru, Ti, Ta, or the like.

As described above, by the semiconductor manufacturing method in accordance with the present embodiment, removal of the oxide film formed on the metal wiring can be carried out stably.

While the invention has been shown and described with respect to the embodiments, it will be understood by those skilled in the art that various changes and modification may be made without departing from the scope of the invention as defined in claims.

For example, in the above embodiments, though the present substrate processing method is applied to the process of removing the surface oxide film of Cu of the underlying wiring exposed through the opening formed by performing etching on the insulating layer, the present invention can also be applied to the case of removing the surface oxide film of Cu in another process. For instance, the present invention can be applied after forming a seed layer or a wiring layer, or after performing a CMP process.

### INDUSTRIAL APPLICABILITY

In accordance with the present invention, a substrate processing method capable of performing substrate processing by using an organic compound gas in a cleanly manner and a semiconductor manufacturing method using the substrate processing method can be provided. Further, a substrate processing apparatus capable of performing the substrate processing method by using the organic compound gas in a cleanly manner and a storage medium storing therein a program for executing the substrate processing apparatus can also be provided.

While the invention has been described with respect to the embodiments, it would be understood by those skilled in the art that various changes and modification may be made without departing from the scope of the invention as defined in the following claims.

This application claims the benefit of Japanese Patent Application No. 2006-228126, filed on Aug. 24, 2006 and Japanese Patent Application No. 2007-149614, filed on Jun. 5, 2007, which are hereby incorporated by reference in its entirety.

What is claimed is:

1. A substrate processing method comprising:
a first step of forming a metal complex by allowing a processing gas containing an organic compound to be adsorbed by a metal layer formed on a target substrate while setting the target substrate to be kept at a first temperature; and
a second step of sublimating the metal complex by heating the target substrate to keep it at a second temperature higher than the first temperature.

2. The substrate processing method of claim 1, wherein the first temperature is set to be of a level at which the vapor pressure of the metal complex becomes lower than a pressure inside a processing space in which the target substrate is maintained.

3. The substrate processing method of claim 1, wherein an oxide film formed on the metal layer is removed by performing the first step and the second step.

4. The substrate processing method of claim 1, wherein the organic compound is selected from a group consisting of carboxylic acid, carboxylic anhydride, ester, alcohol, aldehyde, and ketone.

5. The substrate processing method of claim 1, wherein the first step and the second step are repeated in turn.

6. A manufacturing method for a semiconductor device including a metal wiring and an insulating layer, comprising:
a first step of forming a metal complex by allowing a processing gas containing an organic compound to be adsorbed by a metal layer formed on a target substrate while setting the target substrate to be kept at a first temperature; and
a second step of sublimating the metal complex by heating the target substrate to keep it at a second temperature higher than the first temperature.

7. The manufacturing method of claim 6, wherein the first temperature is set to be of a level at which the vapor pressure of the metal complex becomes lower than a pressure inside a processing space in which the target substrate is maintained.

8. The manufacturing method of claim 6, wherein an oxide film formed on the metal layer is removed by performing the first step and the second step.

9. The manufacturing method of claim 6, wherein the organic compound is selected from a group consisting of carboxylic acid, carboxylic anhydride, ester, alcohol, aldehyde, and ketone.

10. The manufacturing method of claim 6, wherein the first step and the second step are repeated in turn.

11. A substrate processing apparatus comprising:
a processing vessel having therein a processing space in which a target substrate having a metal layer formed thereon is processed;
a gas control unit for controlling a supply of a processing gas into the processing space; and
a temperature control unit for controlling temperature of the target substrate,
wherein the temperature control unit controls the temperature of the target substrate in sequence to keep it at a first temperature for forming a metal complex by allowing a processing gas containing an organic compound to be adsorbed by the metal layer and then to maintain it at a second temperature for sublimating the metal complex.

12. The substrate processing apparatus of claim 11, wherein the first temperature is set to be of a level at which the vapor pressure of the metal complex becomes lower than a pressure inside the processing space.

13. The substrate processing apparatus of claim 11, wherein the organic compound is selected from a group consisting of carboxylic acid, carboxylic anhydride, ester, alcohol, aldehyde, and ketone.

14. The substrate processing apparatus of claim 11, wherein the temperature control unit controls the target substrate to be maintained at the first temperature and then at the second temperature repetitively.

15. A storage medium which stores therein a computer-executable program which controls, when executed, a substrate processing method to be carried out by a substrate processing apparatus comprising:
a processing vessel having therein a processing space in which a target substrate having a metal layer formed thereon is processed;
a gas control unit for controlling a supply of a processing gas into the processing space; and
a temperature control unit for controlling the temperature of the target substrate,
wherein the substrate processing method comprising:
a first step of forming a metal complex by allowing a processing gas containing an organic compound to be adsorbed by a metal layer formed on a target substrate while setting the target substrate to be kept at a first temperature; and
a second step of sublimating the metal complex by heating the target substrate to maintain it at a second temperature higher than the first temperature.

16. The storage medium of claim 15, wherein the first temperature is set to be of a level at which the vapor pressure of the metal complex becomes lower than a pressure inside the processing space.

17. The storage medium of claim 15, wherein the organic compound is selected from a group consisting of carboxylic acid, carboxylic anhydride, ester, alcohol, aldehyde, and ketone.

18. The storage medium of claim 15, wherein the first step and the second step are repeated in turn.

19. A method for removing a metal deposit adhered inside a processing vessel having therein a processing space in which a target substrate having a metal layer formed thereon is processed, comprising:
a step of controlling an internal temperature of the processing vessel and a pressure inside the processing space so as to sublimate the metal deposit.

20. The method of claim 19, wherein the metal deposit is sublimated by being oxidized by an oxidizing gas.

21. The method of claim 19, wherein the oxidizing gas is selected from a group consisting of O₂, O₃, N₂O, and CO₂.

22. The method of claim 19, wherein the internal temperature of the processing vessel is set to be of a level at which the vapor pressure of the metal deposit becomes higher than the pressure inside the processing space.

23. The method of claim 19, wherein an oxide formed on the surface of the metal layer is removed by a processing gas including an organic compound during a process of processing the target substrate having the metal layer formed thereon.

24. The method of claim 23, wherein the organic compound is selected from a group consisting of carboxylic acid, carboxylic anhydride, ester, alcohol, aldehyde, and ketone.

25. A method for removing a metal deposit comprising:
a substrate processing process including a first step of forming a metal complex by allowing a processing gas containing an organic compound to be adsorbed by a metal layer formed on a target substrate while controlling the target substrate to be kept at a first temperature in a processing space inside a processing vessel and a second step of sublimating the metal complex by heating the target substrate to maintain it at a second temperature higher than the first temperature; and
a metal deposit removing process for removing a metal deposit adhered inside the processing vessel by the second step,
wherein in the metal deposit removing process, an internal temperature of the processing vessel and a pressure inside the processing space are controlled so as to sublimate the metal deposit.

26. A substrate processing apparatus comprising:
a processing vessel having therein a processing space in which a target substrate having a metal layer formed thereon is processed;
a supporting table for sustaining the target substrate thereon;
a gas control unit for controlling a supply of a processing gas containing an organic compound into the processing space;
a pressure control unit for controlling a pressure inside the processing vessel; and
a temperature control unit for controlling temperature of at least one of an inner wall surface of the processing vessel and the supporting table to which a metal is adhered,
wherein the gas control unit controls the supply of the processing gas into the processing vessel is stopped in the state the target substrate is not accommodated in the processing vessel, and the pressure control unit and the temperature control unit control the pressure and the temperature, respectively, such that a metal deposit adhered on the inner wall surface of the processing vessel or the supporting table is sublimated.

27. The substrate processing apparatus of claim 26, further comprising a gas control unit for controlling a supply of an oxidizing gas into the processing space.

28. The substrate processing apparatus of claim 27, wherein the oxidizing gas is selected from a group consisting of O₂, O₃, N₂O, and CO₂.

29. The substrate processing apparatus of claim 26, wherein the temperature of the inner wall surface of the processing vessel or the supporting table is set to be of a level at which the vapor pressure of the metal deposit becomes higher than the pressure inside the processing space.

30. The substrate processing apparatus of claim 26, wherein the organic compound is selected from a group consisting of carboxylic acid, carboxylic anhydride, ester, alcohol, aldehyde, and ketone.

31. A storage medium which stores therein a computer-executable program which controls, when executed, a metal deposit removing method to be carried out by a substrate processing apparatus comprising:
a processing vessel having therein a processing space in which a target substrate having a metal layer formed thereon is processed;
a supporting table for sustaining the target substrate thereon;
a gas control unit for controlling a supply of a processing gas containing an organic compound into the processing space;
a pressure control unit for controlling a pressure inside the processing vessel; and
a temperature control unit for controlling temperature of at least one of an inner wall surface of the processing vessel and the supporting table to which a metal is adhered,
wherein in the metal deposit removing process, an internal temperature of the processing vessel and a pressure inside the processing space are controlled so as to sublimate the metal deposit.

32. The storage medium of claim 31, wherein the substrate processing apparatus further includes a gas control unit for controlling a supply of an oxidizing gas into the processing space, and the metal deposit is sublimated by being oxidized by the oxidizing gas.

33. The storage medium of claim 32, wherein the oxidizing gas is selected from a group consisting of O₂, O₃, N₂O, and CO₂.

34. The storage medium of claim 31, wherein the temperature of the inner wall surface of the processing vessel or the supporting table is set to be of a level at which the vapor pressure of a metal deposit becomes higher than the pressure inside the processing space.

35. The storage medium of claim 31, wherein the organic compound is selected from a group consisting of carboxylic acid, carboxylic anhydride, ester, alcohol, aldehyde, and ketone.
